(19) United States
(12) Patent Application Publication
(10) Pub. No.: US 2026/0123131 A1
(43) Pub. Date: Apr. 30, 2026

(54) DISPLAY SCREEN WITH REDUCED TRANSITIONS BETWEEN SUB-PIXELS

(71) Applicant: ALEDIA, Champagnier (FR)

(72) Inventors: Mehdi DAANOUNE, Renage (FR); Tiphaine DUPONT, Grenoble (FR); Sébastien JOUAN, Crolles (FR)

(21) Appl. No.: 19/470,574

(22) PCT Filed: Mar. 28, 2024
(86) PCT No.: PCT/EP2024/058472

§ 371 Date: Sep. 29, 2025

(30) Foreign Application Priority Data
Mar. 30, 2023 (FR) FR2303126

(51) Int. Cl. H10H 29/30; H10H 29/34

(52) U.S. Cl. CPC H10H 29/352; H10H 29/34

(57) ABSTRACT

The invention relates to a display screen comprising a plurality of pixels including at least one first and one second pixel (1000, 2000) that are in contact, the first pixel comprising at least one first subpixel (1100) of a first color (C1), and a second subpixel (1200) of a second color (C2), and the second pixel comprising at least one first subpixel (2100) of the first color and a second subpixel (2200) of the second color, the first subpixels on the one hand and the second subpixels on the other hand being in contact. The screen comprises a set of photoelements (10) comprising a first array of photoelements (100) emitting the first color and a second array of photoelements (200) emitting the second color. The first subpixels and the second subpixels are formed by the first array and the second array of photoelements, respectively.

### TECHNICAL FIELD

The present invention relates in particular to the field of microelectronic and optoelectronic technologies. It finds a particularly advantageous but non-limiting application in display technologies, and in particular in display systems based on LEDs (from English “Light-Emitting Diodes”, translating as light-emitting diodes in French).

### PRIOR ART

A display screen generally comprises a plurality of pixels disposed on a so-called base plane and emitting independently of one another. Each color pixel generally comprises at least three components for emitting and/or converting a light flux, also referred to as subpixels. These subpixels each emit a light flux substantially in a single color (typically red, green and blue). The color of a pixel perceived by an observer comes from the superimposition of the various light fluxes emitted by the subpixels.

Typically, an LED makes it possible to emit the light flux associated with a subpixel. An LED may, in particular, comprise a plurality of active nanowires arranged in a periodic photonic crystal and emitting said light flux at the desired wavelength. This photonic crystal is characterized, in particular, by the diameter of the nanowires and the spacing between the nanowires. Photonic crystals therefore have structural differences from one subpixel to another. These differences lead to design difficulties: the production of a display screen requires the side-by-side manufacture of nanowires having very precise and above all distinct diameters and spacings between them. The dimensions of the zones over which the structural properties of the photonic crystal are constant, i.e. the subpixels, are also very small. It is therefore understood that the manufacture of a display screen involves a succession of technological steps at the scale of a subpixel, which presents significant technical constraints (the need for high precision in the alignment of lithography masks, etc.) and can lead to structural defects (edge effects, etc.). Moreover, the conventional subpixel arrangement within a pixel, shown in FIG. 12, does not exhibit optimal performance.

There is therefore a need to optimize the manufacture of display screens, as well as to improve the performance of self-emitting pixels based on nanowires.

### SUMMARY

In order to achieve this objective, according to one embodiment a display screen is provided comprising:
a plurality of pixels comprising at least a first pixel and a second pixel, the first pixel and the second pixel being in contact, the first pixel comprising at least one first subpixel of a first color, and the second pixel comprising at least one first subpixel of the first color, the first subpixel of the first pixel and the first subpixel of the second pixel being in contact, and
a set of photoelements comprising at least one first continuous array of photoelements which emits in a first wavelength range corresponding to the first color.

The device is further characterized in that the first subpixel of the first pixel and the first subpixel of the second pixel are both formed by the first array of photoelements.

One important challenge of display technologies relates to the transition zones between adjacent pixels and subpixels. Indeed, in display screens, subpixels of distinct colors are typically adjoined to each other. When a subpixel of a given color is formed by a photonic crystal, this photonic crystal has structural features (diameter of the nanowires, spacing between neighboring nanowires, etc.) different from those of a photonic crystal forming a neighboring subpixel emitting in another color. Abrupt transition zones separate these subpixels. The presence of these abrupt transition zones has the disadvantage of breaking the symmetry of the array and, therefore, creating detrimental edge effects during nanowire growth. Moreover, the dimensions of the different photonic crystals forming the different subpixels correspond to the dimensions of the latter and are therefore very small. However, the performance level of a photonic crystal is highly dependent on the amount of nanowires constituting it and its dimensions: a photonic crystal of a smaller size has worse performance than a photonic crystal of a larger size. Thus, in the present state of the art, and in particular in the case of monolithic screens, in which the dimensions of the subpixels are typically very small, the quality of the photonic crystals forming the photoelement arrays is limited.

Arranging the subpixels so that subpixels of the same color and belonging to neighboring pixels are in contact reduces the number of abrupt transition zones. Indeed, two subpixels of the same color are formed by photonic crystals having the same structural properties. There is no abrupt transition zone between them.

If, for example, two pixels are considered, each comprising two subpixels of two distinct colors, the contact between these pixels being made, as is usually the case, between a subpixel of the first pixel of a first color and a subpixel of the second pixel of a second color, it is usually possible to count, on the scale of these two pixels, three abrupt transition zones: one within each pixel and one at the interface between the two pixels. By bringing the two pixels into contact at subpixels having the same color, i.e. formed by arrays of substantially identical photoelements, one of the three abrupt transition zones is removed. This reasoning can be extended to the scale of a full display screen, including up to millions of pixels. It is therefore understood that the placing in contact of subpixels of the same color makes it possible to improve the quality of the photoelement arrays and therefore of the screen itself.

In addition, by placing in contact two subpixels of the same color, an array of photoelements is created that is common to the two subpixels. By definition, this common array of photoelements has dimensions greater than those of an array forming a single subpixel. The array forming two neighboring subpixels of the same color can thus be formed more easily than two separate arrays corresponding to each of the two subpixels. The photonic crystal forming the array, by construction also of larger dimensions than the photonic crystals used in the same context in the prior art, also has better performance due to the increase in its dimensions. The proposed disposition therefore makes it possible to optimize the manufacture of the display screen, limit the appearance of structural defects and improve the visual rendering.

### BRIEF DESCRIPTION OF THE DRAWINGS

The goals, objects, features and advantages of the invention will be better understood from the detailed description of an embodiment of the latter which is illustrated by the following accompanying drawings wherein:

FIG. 1 shows a sectional view of an intermediate manufacturing step of the photoelements included in a display screen according to one of the embodiments of the invention.

FIGS. 2A and 2B show embodiments of the invention, wherein the display screen comprises two pixels each comprising two subpixels.

FIG. 3 shows an embodiment of the invention, wherein the display screen comprises two pixels each comprising three subpixels.

FIGS. 4, 5 and 6 show embodiments of the invention, wherein the display screen comprises three pixels.

FIGS. 7, 8, 9A and 9B show embodiments of the invention wherein the display screen comprises four pixels.

FIG. 10 illustrates a particular embodiment of the invention.

FIG. 11 shows a sectional view of a display screen according to the invention and illustrates, in particular, a control electronics for powering the photoelements.

FIG. 12 shows a display screen according to the prior art comprising four pixels and having abrupt transition zones between all the subpixels.

The drawings are given as examples and do not limit the invention. They constitute schematic representations intended to facilitate understanding of the invention and are not necessarily drawn to scale for practical applications. In particular, the dimensions are not representative of reality.

### DETAILED DESCRIPTION

Before undertaking a detailed review of embodiments of the invention, optional features are listed below, which can optionally be used in combination or alternatively:

According to one advantageous embodiment, the first pixel comprises a second subpixel of a second color and the second pixel comprises a second subpixel of the second color, the second subpixel of the first pixel and the second subpixel of the second pixel being in contact, the display screen further comprising a second continuous array of photoelements which emits in a second wavelength range corresponding to the second color, the first wavelength range and the second wavelength range being distinct, the second subpixel of the first pixel and the second subpixel of the second pixel both being formed by the second array of photoelements.

According to one embodiment:
the first pixel further comprises a third subpixel of a third color,
the second pixel further comprises a third subpixel of the third color,
the set of photoelements comprises a third continuous photoelement array which emits in a third wavelength range corresponding to the third color, the third wavelength range being distinct from the first wavelength range and the second wavelength range,
   and the third subpixel of the first pixel and the third subpixel of the second pixel are in contact and both formed by the third array of photoelements.

According to one embodiment, the plurality of pixels comprises at least one third pixel in contact with the first pixel, the first pixel further comprises a third subpixel of a third color, the second pixel further comprises a third subpixel of the third color, and the third pixel comprises at least one third subpixel of the third color, the third subpixel of the first pixel and the third subpixel of the third pixel being in contact. In this same embodiment, the set of photoelements comprises a third array of photoelements which emits in a third wavelength range corresponding to the third color, the third wavelength range being distinct from the first wavelength range and the second wavelength range. The third subpixel of the first pixel and the third subpixel of the third pixel are then both formed by the third array of photoelements.

According to one embodiment, the contact between the first pixel and the second pixel is made along a first contact line, and the contact between the first pixel and the third pixel is made along a second contact line, the first contact line and the second contact line being parallel and non-intersecting.

According to one embodiment, the contact between the first pixel and the second pixel is made along a first contact line and the contact between the first pixel and the third pixel is made along a second contact line, the first contact line and the second contact line forming an angle, referred to as the contact angle, of between 5° and 175°, preferably between 30° and 150°.

According to an advantageous example, the contact angle is equal to 120°. This is particularly the case when the pixels each have a regular hexagon shape.

According to one embodiment, the contact between the first pixel and the second pixel is made along a first contact line, and the contact between the first pixel and the third pixel is made along a second contact line, the first contact line and the second contact line being perpendicular. Thus, according to an advantageous example, the contact angle is equal to 90°. This is particularly the case when the pixels each have a rectangular or even square shape.

According to one embodiment, the third pixel further comprises a second subpixel of the second color in contact with the second subpixel of the first pixel, and the second subpixel of the third pixel is formed by the second array of photoelements.

According to one embodiment, the plurality of pixels comprises at least one fourth pixel in contact with the second pixel and the third pixel, the fourth pixel comprising at least one second subpixel of the second color, the second subpixel of the second pixel and the second subpixel of the fourth pixel on the one hand and the second subpixel of the third pixel and the second subpixel of the fourth pixel on the other hand, being in contact, and the second subpixel of the fourth pixel is formed by the second array of photoelements.

According to one embodiment, the second pixel further comprises a third subpixel of the third color and the fourth pixel further comprises a third subpixel of the third color, the third subpixel of the second pixel and the third subpixel of the fourth pixel being in contact and both being formed by a third secondary continuous array of photoelements which emits in the third wavelength range.

According to one embodiment, the third pixel further comprises a first subpixel of the first color and the fourth pixel comprises at least one first subpixel of the first color, the first subpixel of the third pixel and the first subpixel of the fourth pixel being in contact and both being formed by a first secondary continuous array of photoelements which emits in the first wavelength range.

According to an advantageous example, the first array of photoelements extends over at least two pixels other than the first pixel and the second pixel.

According to an advantageous example, each array of photoelements is common to at least two adjacent pixels, preferably to at least four adjacent pixels.

According to an advantageous example, each array of photoelements forming a subpixel of the first pixel also forms at least one subpixel of at least one pixel adjacent to the first pixel. This may also be the case for any other pixel of the plurality of pixels.

According to an advantageous embodiment, the photoelements are configured to emit a beam whose intensity in a direction perpendicular to an upper face of a substrate from which said photoelements extend is at least 20% greater than the maximum intensity of an emission by a Lambertian light source for which the total light flux over 4π sr is equal to the total flux over 4π sr of the beam emitted by the photoelements.

According to a preferred example, the first array of photoelements forms a photonic crystal.

According to one embodiment, the display further comprises a plurality of separate electrical contacts, each electrical contact being configured to power the photoelements of an array of photoelements forming a distinct subpixel.

According to one example, the photoelements are nanowires.

According to an advantageous embodiment, the display comprises a monolithic support carrying all of the pixels of the pixel array. Thus, advantageously, the display screen was produced from the support without successive cutting and gluing of the latter. For example, the display screen may have been manufactured by, among other things, epitaxy of photoelements from this single monolithic support.

According to one embodiment, the display screen comprises at least two distinct electrical contacts, one being configured to power the photoelements of the first array of photoelements forming the first subpixel of the first pixel, and the other being configured to power the photoelements of the first array of photoelements forming the first subpixel of the second pixel. In the present invention, the display screen is a single continuous screen having a face configured to display an image at a given time.

Here, photoelement means an element capable of emitting a light beam. A photoelement may, for example, be an active 3D structure, for example an active wire or nanowire.

A 3D structure is said to be active when it comprises an active region and is electrically connected, thus enabling it to emit light radiation.

Wire or nanowire means a 3D structure of elongate shape in the longitudinal direction. The longitudinal dimension of the 3D structure, along z in the figures, is greater, and preferably very much greater, than the transverse dimensions of the 3D structure, in the plane xy in the figures. For example, the longitudinal dimension is at least five times, and preferably at least ten times, greater than the transverse dimensions. A nanowire is a wire with cross-sectional dimensions of less than 2 μm (1 μm=10⁻⁶ m).

Diameter of a nanowire means the largest transverse dimension of this nanowire. In the present invention, the 3D structures do not necessarily have a circular cross-section. The 3D structures may, in particular, have a hexagonal or polygonal cross-section. In particular, in the case of 3D structures based on GaN, this cross-section may be hexagonal. The diameter then corresponds to a mean diameter calculated from the diameter of a circle inscribed in the polygon of the cross-section and from the diameter of a circumscribed circle of this polygon.

In the present patent application, the terms “light-emitting diode”, “LED” or simply “diode” are used as synonyms. An “LED” may also be understood as a “micro-LED”. A “micro-LED” is an LED whose dimensions do not exceed 1 mm (1 mm=10⁻³ m).

Hereinafter, the following abbreviations relating to a material M are optionally used:
M-i refers to the intrinsic or unintentionally doped material M, according to the terminology normally used in the microelectronic field for the suffix -i.
M-n refers to the N, N+ or N++ doped material M, according to the terminology normally used in the microelectronic field for the suffix -n.
M-p refers to the P, P or P++ doped material M, according to the terminology normally used in the microelectronic field for the suffix -p.

A substrate, a layer or a device, “based on” a material M is taken to mean a substrate, a layer or a device comprising only this material M or this material M and optionally other materials, for example alloying elements, impurities or doping elements. Thus a 3D structure based on gallium nitride (GaN) can for example comprise gallium nitride (GaN or GaN-i) or doped gallium nitride (GaN-p, GaN-n). An active region based on gallium-indium nitride (InGaN) can for example comprise gallium-aluminum nitride (AlGaN) or gallium nitride with various proportions of aluminum and indium (GaInAlN). In the context of the present invention, the material M is generally crystalline.

A reference frame, preferably orthonormal, comprising the axes x, y, z is shown in the appended figures.

The terms “substantially”, “about”, “of the order of” mean, when they relate to a value, “to within 10%” of this value or, when they relate to an angular orientation, “to within 10°” of this orientation. Thus a direction substantially normal to a plane means a direction having an angle of 90±10° with respect to the plane.

To determine the geometry of the 3D structures and the compositions of the various elements (wire, active region, collar for example) of the 3D structures, scanning electron microscopy (SEM) or transmission electronic microscopy (MET or TEM, English short for “Transmission Electronic Microscopy”) or scanning transmission electron microscopy STEM (English short for “Scanning Transmission Electron Microscopy”) analyses can be carried out.

TEM or STEM lend themselves particularly well to observing and identifying quantum wells—the thickness of which is generally of the order of a few nanometers—in the active region. Various techniques listed below non-exhaustively can be implemented: dark field (dark field) and bright field (bright field) imaging, weak beam (weak beam) imaging, high angle annular dark field HAADF (English short for “High Angle Annular Dark Field”) imaging.

The chemical compositions of the various elements can be determined by means of the well-known EDX or X-EDS method, which stand for “energy dispersive x-ray spectroscopy” which means “energy dispersive x-ray spectroscopy”.

This method is well suited to analyzing the composition of small-sized optoelectronic devices such as 3D LEDs. It can be implemented on metallurgical sections in a scanning electron microscope (SEM) or on thin plates in a transmission electron microscope (TEM).

The optical properties of the various elements, and in particular the main emission wavelengths of 3D LEDs based on GaN and/or active regions based on InGaN, can be determined by spectroscopy.

Cathodoluminescence (CL) and photoluminescence (PL) spectroscopies are well suited to optically characterizing the 3D structures described in the present invention.

The above-mentioned techniques make it possible, in particular, to determine whether an optoelectronic device with an axial 3D structure in the form of a wire comprises InGaN-based quantum wells formed at the top of a GaN-based wire, and a masking layer indicating implementation of a MOVPE-type deposition.

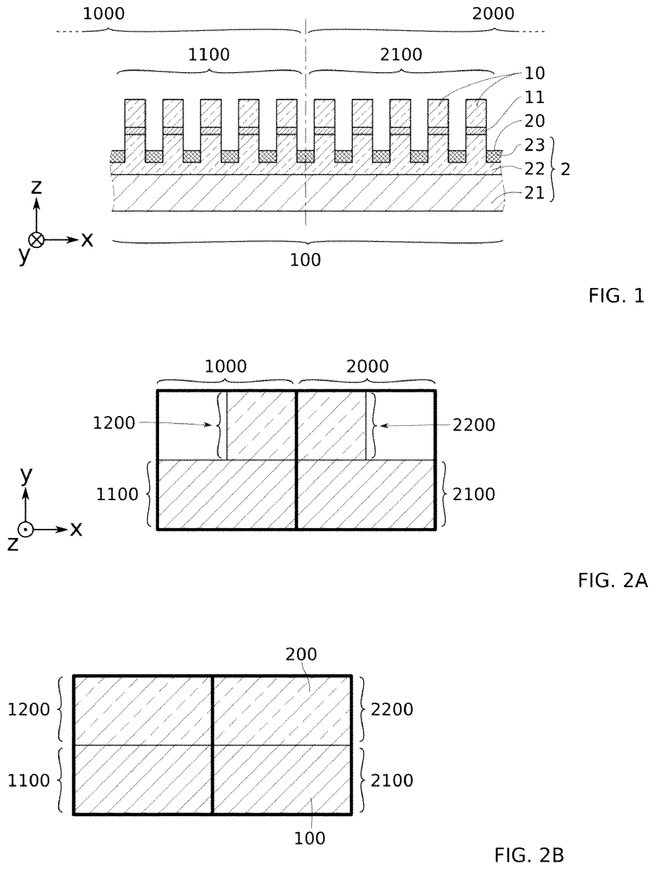

A display screen according to one embodiment of the invention will now be described with reference to FIGS. 1 to 2B.

The display screen extends mainly in the plane xy shown in FIGS. 1 and 2A. It comprises a set of photoelements 10, for example 3D structures of the nanowire type. These photoelements 10 typically extend from a substrate 2 extending in the plane xy. The substrate has an upper face 20 also extending in the plane xy. The substrate 2 can be in the form of a stack comprising, for example, in the direction z, a support 21, a surface layer referred to as a nucleation layer 22, and a masking layer 23, as shown in FIG. 1.

In particular, the substrate 21 may be made of sapphire in order to limit the lattice parameter discrepancy with GaN if the photoelements 10 are made of this material, or of silicon to reduce costs and for technological compatibility problems. In the latter case, it may be in the form of a wafer with a diameter of 200 mm or 300 mm. In particular, it serves as a support to the 3D structures.

The nucleation layer 22 is preferably based on AlN. Alternatively, it can be based on other metal nitrides, for example GaN or AlGaN. It can be formed on the silicon support 21 by epitaxy, preferably by MOVPE (the acronym for Metalorganic Vapor Phase Epitaxy). In a known manner, one or more intermediate buffer layers can be disposed between the nucleation layer 22 and the support 21. According to one example, the nucleation layer 22 has a thickness of between 1 nm and 10 μm. It preferably has a thickness of the order of a few hundreds of nanometers, for example approximately 100 nm or 200 nm, to a few microns, for example of order 2 μm. It may also have a thickness of less than 100 nm. Such a thickness can limit the appearance of structural defects in the nucleation layer 22. In particular, the growth of this nucleation layer 22 may be pseudomorphic, i.e. the epitaxy stresses (related in particular to the difference in lattice parameters between Si and AlN, GaN or AlGaN) may be elastically relaxed during the growth. Thus the crystalline quality of this nucleation layer 22 may be optimized.

Preferably, the masking layer 23 is made of a dielectric material, for example silicon nitride Si₃N₄. It can be deposited by chemical vapor deposition (CVD) on the nucleation layer 22. It partially masks the nucleation layer 22 and comprises preferably circular openings exposing areas of the nucleation layer 22. These openings typically have different dimensions, for example different diameters, according to the areas considered, in particular the areas corresponding to the first LED and/or the first transition zone and/or the second LED and/or the second transition zone, etc. Openings can be distributed evenly within each area, for example in the form of an ordered array. Different spacings d, i.e. the distance separating the centers of two adjacent openings, can be defined according to said areas and in particular, as will be described later, according to the subpixels. For example, the openings may be made by UV or DUV (the acronym for Deep UV) lithography, by electron beam lithography, or by NIL (the acronym for Nanoinprint Lithography). Such a masking layer 23 allows localized growth of a 3D structure such as a nanowire from the nucleation layer 22 and at each opening. The lower part of the 3D structure then bears on the nucleation layer of the substrate 2 via its base.

The set of photoelements 10 is continuous and is distributed over the entire screen in its dimensions in the x and y directions.

Here, “photoelement” means an active element, i.e. capable of emitting radiation, but it is understood that each of these elements can be electrically powered or not and thus be switched “on” or “off”.

An active photoelement 10 or active nanowire 10 comprises an active region 11 and is typically electrically connected. This active region 11 is the site of radiative recombinations of electron-hole pairs making it possible to obtain light radiation having a principal wavelength. The active region 11 typically comprises a plurality of quantum wells, for example formed by emissive layers based on GaN, InN, InGaN, AlGaN, AlN, AlInGaN, GaP, AlGaP, AlInGaP, AlGaAs, GaAs, InGaAs, or AlInAs, or a combination of several of these materials.

The set of photoelements 10 comprises a first array 100 of photoelements and a second array 200 of photoelements. An array of photoelements is defined as a subset of the set of photoelements 10. An array of photoelements within the meaning of the invention is continuous, i.e. the photoelements that comprise it are arranged regularly, according to a given spacing, possibly a plurality of given spacings defined in different spatial directions. The fact that an array is continuous is also characterized by the fact that all the photoelements that compose it are based on the same material and have the same dimensions (typically the same diameter). In this sense, it can be said that the photoelements of a same array are homogeneous and regular. It is understood that the homogeneity and regularity of an array of photoelements is to be assessed by taking into account the manufacturing error margins of the latter. Furthermore, a continuous array has no walls within it.

Each of these arrays forms a photonic crystal and can be defined by several parameters, in particular:
the emission wavelength,
the array spacing
the filling ratio, also referred to as the opening ratio or density, generally between 10 and 90%,
the lattice type (hexagonal, square, etc.),
the refractive index of the material filling the spaces between the nanowires 101, normally referred to as a “filler” (English term translating to “filler”), is preferably between 1 and 1.7, and
the materials constituting the photoelements, and
the dimensions of the nanowires.

The emission of each of the arrays is preferably carried out mainly in a direction perpendicular to the upper face 20 of the substrate 2. According to one advantageous example, the photoelements are configured to emit a beam, the intensity of which in a direction perpendicular to the upper face 20 of the substrate 2 (referred to as normal to the substrate) is at least 20% greater than the maximum intensity of a Lambertian light emission whose total light flux over 4π sr is equal to the total flux over 4π sr of the beam emitted by the photoelements. The light intensities in question are typically expressed in W.sr−1 (watts per steradian).

Advantageously, the light flux emitted by each of the arrays in a cone defined by an angle of substantially 30° with respect to the normal to the substrate 2 is two times higher, preferably three times higher, and very advantageously four times higher, than if the beam came from a Lambertian source. Advantageously, the light intensity emitted by each of the arrays along the normal to the substrate 2 is two times higher, preferably four times higher, and very advantageously fifteen times higher, than if the beam came from a Lambertian source.

An emission directed mainly perpendicular to the upper face 20 of the substrate 2 makes it possible to prevent the photoelements corresponding to a pixel or subpixel from illuminating the photoelements of a neighboring pixel or subpixel. Thus, isolation of the illumination of the different pixels or subpixels is ensured without the need to produce walls between these elements. This avoids breaking the continuity and symmetry of the photonic crystals formed by the photoelement arrays. In other words, the fact that the photoelements emit mainly perpendicularly to the upper face 20 of the substrate 2 makes it possible to increase the dimensions of the photonic crystals and therefore to improve their quality.

The first array 100 of photoelements emits in a first wavelength range corresponding to a first color C1, while the second array 200 of photoelements emits in a second wavelength range corresponding to a second color C2 distinct from the first color.

The photoelements of the same array have diameters substantially equal to a target value. It is understood that, due to the inaccuracies arising from the manufacturing processes, it is difficult for all the photoelements of a same array to have a diameter equal to this target value. The variations in the value of the diameter of a nanowire for example due to manufacturing uncertainties can be estimated to be approximately 10% of the target value. The same applies to the value of the spacing between two neighboring photoelements. For this reason, not all photoelements emit at exactly the same wavelength. The photoelements of a photoelement array emit in a wavelength range characterizing the array. It is understood that an array of N photoelements each emitting a light radiation characterized by a wavelength λi with 1≤i≤N, λi being within the emission range of the array, and all having the same intensity, emits a global radiation at a wavelength of the array, λarray, defined by:

$${λ}_{array} = \frac{{\sum }_{i = 1}^{N} {λ}_{i}}{N}$$

In particular, the array wavelengths λ₁₀₀, λ₂₀₀ of the first array of photoelements 100 and of the second array of photoelements 200 are defined in this way. Of course, if not all photoelements emit with the same intensity, the different components of the array wavelength, i.e. the wavelengths of the radiations emitted by each of the photoelements, can be weighted by coefficients relative to their respective intensities.

The first array of photoelements 100 and the second array of photoelements 200 emit radiations corresponding to distinct colors C1 and C2. It is considered that the two wavelength ranges of the two arrays 100, 200 are distinct if the array wavelengths λ₁₀₀, λ₂₀₀ characterizing them, comply with the following relationship:

$$\vert {λ}_{100} - {λ}_{200} \vert > 30 nm$$

In practice, the wavelengths λ₁₀₀, λ₂₀₀ characterizing the colors C1, C2 of the first array 100 and the second array 200 respectively, belong to very far-apart ranges. For example, λ₁₀₀ is in a range corresponding to a shade of red (between 620 and 800 nm), green (between 520 and 565 nm) or blue (between 430 and 520 nm), and λ₂₀₀ is in another of these ranges. These ranges are around the wavelengths set by the International Commission on Illumination (CIE) for the three physical primary colors: 700 nm for red, 536.1 nm for green and 435.8 nm for blue. Ideally, the wavelengths emitted by the photoelement arrays are close to these values.

The photonic crystals formed by the photoelement arrays are preferably sized and configured to amplify the emission of the photoelements. For a given photonic crystal, this amplification is effective in the wavelength range corresponding to the color emitted by said photonic crystal. As will appear later, this color corresponds to that of the subpixel formed by the photonic crystal considered.

The display further comprises a plurality of pixels. This plurality of pixels comprises, in particular, a first pixel 1000 and a second pixel 2000. The first pixel 1000 and the second pixel 2000 are in contact.

Each of the pixels of the plurality of pixels comprises at least a first subpixel and a second subpixel. Thus, in particular, a first subpixel 1100 of the first pixel, a second subpixel 1200 of the first pixel, a first subpixel 2100 of the second pixel, and a second subpixel 2200 of the second pixel are defined, all shown in FIG. 2A.

Each subpixel has a color in the visible range. More specifically, the first subpixels 1100, 2100 are of the first color C1 and the second subpixels 1200, 2200 are of the second color C2.

As illustrated in FIGS. 2A and 2B:
the first subpixel 1100 of the first pixel and the first subpixel 2100 of the second pixel are in contact, and
the second subpixel 1200 of the first pixel and the second subpixel 2200 of the second pixel are also in contact.

FIG. 2A illustrates an embodiment in which each of the pixels 1000, 2000 comprises more than two subpixels. FIG. 2B shows, in turn, a case where each of the pixels 1000, 2000 consists of two subpixels only.

The display screen can be characterized by its set of photoelements or by its set of pixels. However, these two sets are fully linked because the various subpixels are formed by the various arrays of photoelements. More specifically, the first subpixels 1100, 2100 are, in particular, formed by the first array of photoelements 100 and the second subpixels 1200, 2200 are, in particular, formed by the second array of photoelements 200. This correspondence is found in particular in the fact that the first array 100 emits radiation at a first array wavelength λ₁₀₀ corresponding to the first color C1 and that the first subpixels 1100, 2100 are of this first color C1. The same applies to the color C2 of the second subpixels 1200, 2200, generated by the second array 200.

An array of photoelements thus consists of at least one region, and typically a plurality of regions, forming at least one pair of adjacent subpixels. These regions are continuous and consist of photoelements with substantially identical structural features, except for manufacturing errors. In the prior art, an array corresponds to only a single region, itself corresponding to a single subpixel. In this way, the dimensions of the arrays are optimized. This has many advantages. Firstly, this arrangement makes it possible to reduce the number of transition zones between arrays forming distinct photonic crystals. The number of zones creating symmetry breaks is therefore reduced. Since these areas are responsible for growth defects and losses in optical quality, the quality of the photoelement array and ultimately that of the display screen is improved. Moreover, the formation of the photoelements is facilitated. More specifically, the latter is carried out by successive masking and deposition steps, which are all the more complex to carry out as the arrays are of small dimensions. In particular, the smaller the dimensions of the areas on which photoelements are to be formed, the more precisely aligned photolithography masks are required to be. In addition, increasing the dimensions of a continuous photonic crystal of photoelements, and therefore the number of photoelements that compose it, makes it possible to improve its ability to discriminate waves according to their wavelength. In other words, the more extensive the photonic crystal, the better the control and amplification of the wavelengths propagating there. Furthermore, increasing the dimensions of the photonic crystal improves its ability to ensure good emission directionality. This plays an important role, in particular, in the possibility of doing without walls between adjacent subpixels and/or pixels.

A photonic crystal can function as such from three rows of photoelements. The larger the number of photoelement rows forming the photonic crystal, the better the photonic crystal quality. Thus, advantageously, the photonic crystals are each formed by at least 10 rows, preferably 20 rows, and more preferably 50 rows of photoelements.

According to one embodiment, the set of photoelements comprises a third array 300 of photoelements. The structural properties of the first and second arrays 100, 200 can be applied, mutatis mutandis, to the third array 300. The third array 300 of photoelements emits in a third wavelength range, corresponding to a third wavelength λ300 and a third color C3. Preferably, the third wavelength λ300 is in the third range from the previously mentioned wavelength ranges. For example, if the first color C1 corresponded to a shade of red and the second color C2 to a shade of blue, then the third color C3 typically corresponds to a shade of green.

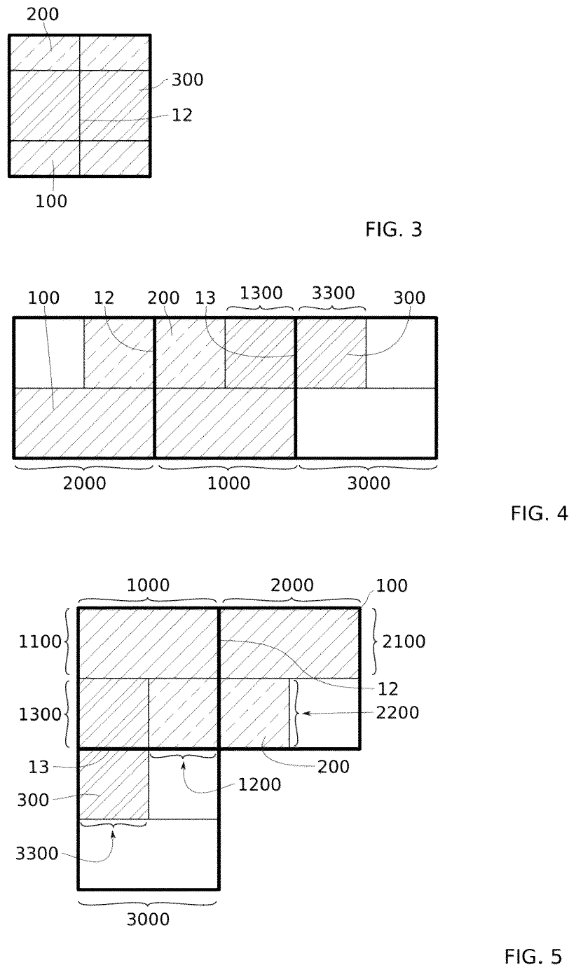

This third array 300 of photoelements makes it possible to form a plurality of third subpixels. FIG. 3 illustrates, in particular, an embodiment in which the first pixel 1000 comprises a third subpixel referred to as the third subpixel 1300 of the first pixel and the second pixel 2000 comprises a third subpixel referred to as the third subpixel 2300 of the second pixel. The second subpixels 1200, 2200 on the one hand and the third subpixels 1300, 2300 on the other hand are advantageously in contact.

According to one embodiment, the plurality of pixels comprises a third pixel 3000 in contact with the first pixel 1000. This third pixel 3000 comprises at least one third subpixel 3300 in contact with and formed by the same third array of photoelements 300 as the third subpixel 1300 of the first pixel.

As illustrated in FIGS. 4 and 5, the first pixel 1000 and the second pixel 2000 are in contact and this contact is made along a line referred to as the first contact line 12. The contact between the first pixel 1000 and the third pixel 3000 is made along a line referred to as the second contact line 13. According to an example illustrated in FIG. 4, the first contact line 12 and the second contact line 13 are parallel. In this case, the second pixel 2000 and the third pixel 3000 are located on either side of the first pixel 1000. According to an example illustrated in FIG. 5, the first contact line 12 and the second contact line 13 are perpendicular. In the typical case of square-shaped pixels, the second pixel 2000 and the third pixel 3000 border adjacent sides of the first pixel 1000. This pooling of the third array of photoelements 300 between the third subpixel 1300 of the first pixel and the third subpixel 3300 of the third pixel has the same advantages as pooling the first array 100 and the second array 200 between the first subpixels 1100, 2100 and second subpixels 1200, 2200. It is understood that combining the placing in contact of subpixels of the same color, and the pooling of photonic crystals, can increasingly reduce the number of abrupt transitions 5 between subpixels as shown for example in FIG. 12.

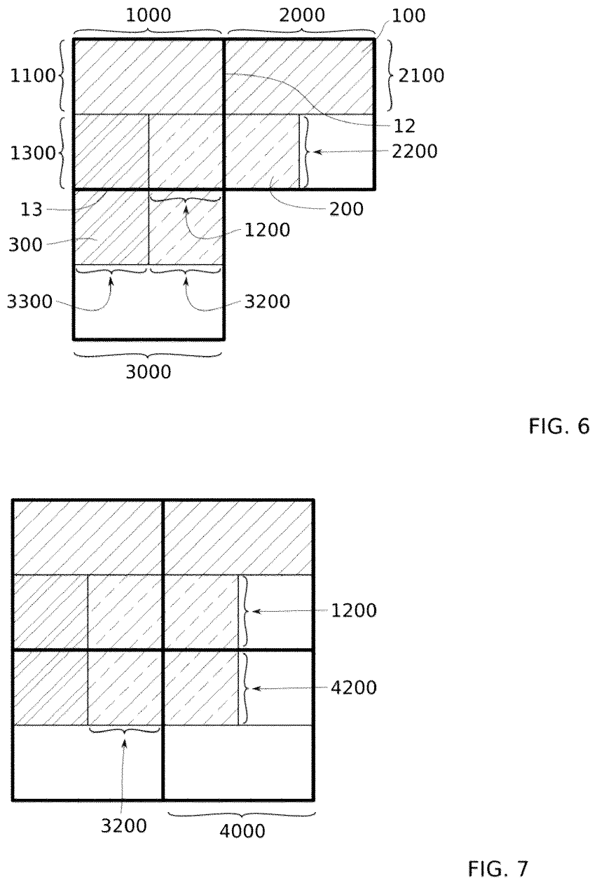

Still with the aim of pooling the arrays of photoelements, the third pixel 3000 may comprise a second subpixel 3200 in contact with the second subpixel 1200 of the first pixel. The second array 200 then forms not only the second subpixel 1200 of the first array and the second subpixel 2200 of the second array, but also the second subpixel 3200 of the third array (as illustrated in FIG. 6). The corresponding photonic crystal thus extends over three subpixels 1200, 2200, 3200.

According to one embodiment, the plurality of pixels comprises a fourth pixel 4000 in contact with the first pixel 1000 and with the third pixel 3000. As illustrated in FIG. 7, this fourth pixel 4000 comprises at least one second subpixel 4200 in contact with the second subpixel 1200 of the first pixel and with the second subpixel 3200 of the third pixel. The second array 200 then forms the second subpixels 1200, 2200, 3200, 4200 of the set of four pixels 1000, 2000, 3000, 4000.

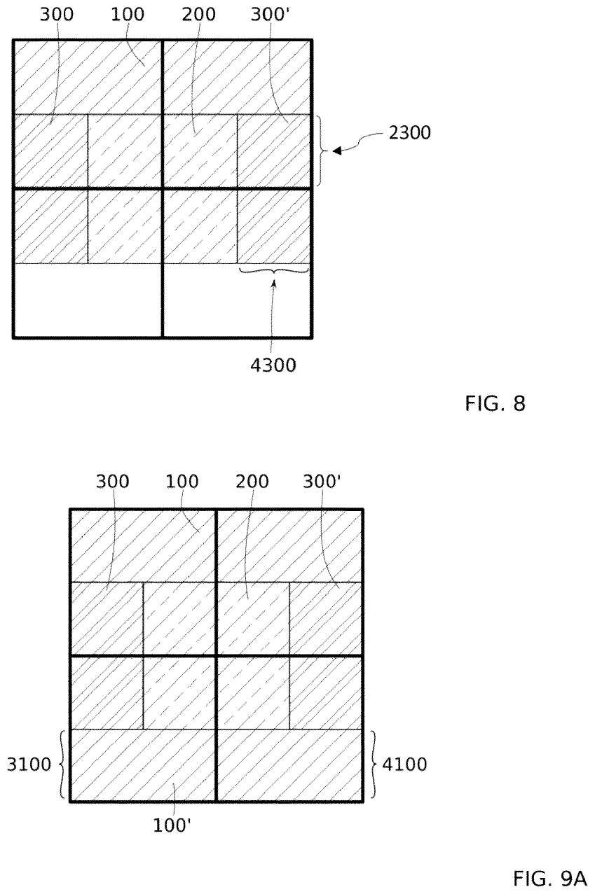

As illustrated in FIG. 8, according to one embodiment, the second pixel 2000 and the fourth pixel 4000 each comprise a third subpixel 2300, 4300. These two subpixels are in contact and are both formed by a third secondary array 300′ of photoelements having the same characteristics as the third array 300. The third secondary array 300′ and the third array 300 can, in particular, be manufactured simultaneously.

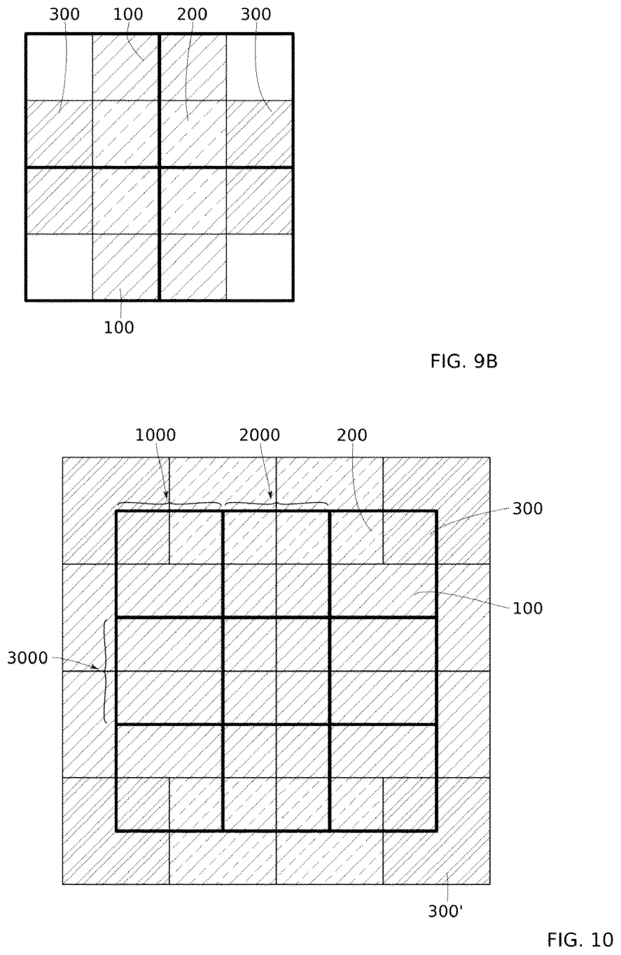

As illustrated in FIGS. 9A and 9B, according to one embodiment, the third pixel 3000 and the fourth pixel 4000 each comprise a first subpixel 3100, 4100. These two subpixels are in contact and are both formed by a first secondary array 100′ of photoelements having the same characteristics as the first array 100. The first secondary array 100′ and the first array 100 can, in particular, be manufactured simultaneously. It can be seen in FIG. 9A that the pixels consist of three subpixels only. FIG. 9B illustrates an embodiment in which the pixels comprise a fourth subpixel, which may for example be formed by an array of photoelements shared with a subpixel of a neighboring pixel (not shown).

FIG. 10 illustrates a particular embodiment, in which some pixels are of a single color and adjoin subpixels of the same color and belonging to adjacent pixels. For example, as illustrated, the third pixel 3000 is integrally formed by the first array 100, which also forms the first subpixel 1100 of the first pixel and the first subpixel 2100 of the second pixel.

It is understood that the principle of placing subpixels of the same color in contact and putting photonic crystals of the same structure together can be extended to a number of pixels greater than four. This idea is also applicable regardless of the number of subpixels included in each of the pixels. The distribution of the different arrays of photoelements will depend on the pixel geometry and the arrangement of the subpixels within the pixels. It should be noted that a highly optimized screen can be obtained by repeating the patterns described above. For example, by repeating, in the plane xy, the pattern consisting of the four pixels illustrated in FIG. 9A, continuous sets of similar photoelements (of the type of those forming the third array 300 and the third secondary array 300′) are created extending over four subpixels and no longer just two. Similarly, continuous sets of photoelements of the type of those of the first array 100 may be obtained.

Regardless of the number of pixels and subpixels and the arrangement of the subpixels in each of the pixels, the aim is always to limit the number of contacts between subpixels of different colors.

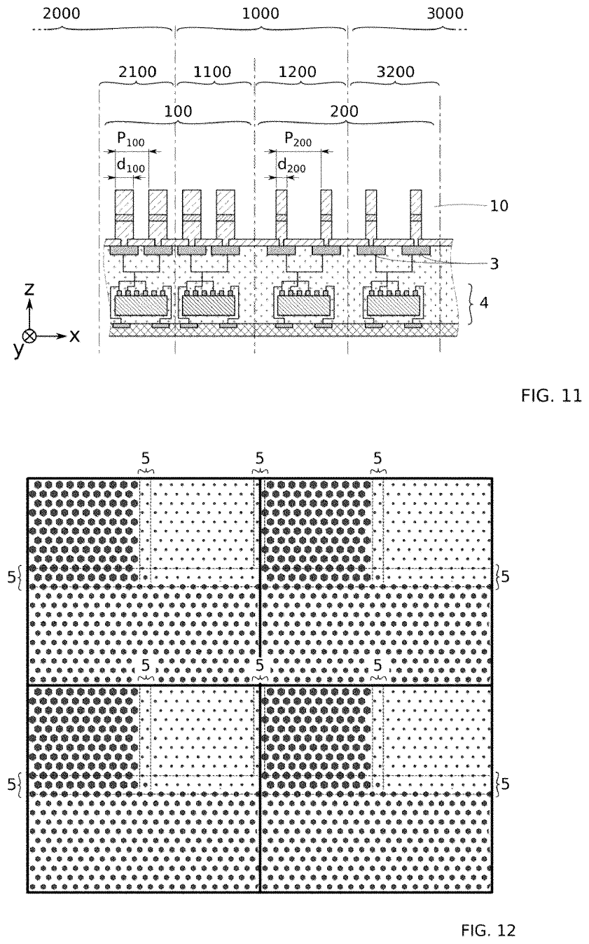

As illustrated in FIG. 11, the display screen advantageously comprises electrical contacts 3 for electrically powering the photoelements. These electrical contacts 3 may be common to a plurality of photoelements. Preferably, photoelements belonging to arrays forming distinct subpixels are powered separately. Thus, even if the arrays forming two neighboring subpixels have been formed simultaneously and form a continuous array of photoelements, the two subpixels remain electrically independent. It may indeed also be necessary, in order for the image to be rendered, that both subpixels are on, that both subpixels are off, or that only one is on.

These electrical contacts 3 are connected to a control electronics 4 for controlling the switching on or off of the photoelements according to the display needs. The representation in FIG. 11 of the control electronics 4 is only illustrative. In particular, the assignment of the various transistors to the various photoelements, as well as their connections, are in no way limiting. For example, the photoelements are, in addition, typically connected at another pole to an electrical connection not shown for reasons of clarity.

FIG. 11 further illustrates the juxtaposition of three pixels 1000, 2000, 3000. In particular, there is a cross-sectional view of the first subpixel 2100 of the second pixel, the first subpixel 1100 of the first pixel, the second subpixel 1200 of the first pixel and the second subpixel 3200 of the third pixel. The first array 100 is formed of photoelements having a first target diameter d100 and a first target spacing between them p100. The second array 200 is formed by photoelements having a second target diameter d200 and a second target spacing p200 between them. As illustrated, each of these arrays forms two adjacent subpixels belonging to neighboring pixels: the first array 100 forms the first subpixel 2100 of the second pixel and the first subpixel 1100 of the first pixel, while the second array 200 forms the second subpixel 1200 of the first pixel and the second subpixel 3200 of the third pixel.

The invention is not limited to the embodiments described above and extends to all the embodiments covered by the invention.

1. A display screen comprising:
a plurality of pixels comprising at least one first pixel, a second pixel and a third pixel, the first pixel and the second pixel being in contact, the first pixel and the third pixel being in contact, the first pixel comprising at least one first subpixel of a first color, a second subpixel of a second color and a third subpixel of a third color, the second pixel comprising at least one first subpixel of the first color, a second subpixel of the second color and a third subpixel of the third color, and the third pixel comprises at least one third subpixel of the third color, the first subpixel of the first pixel and the first subpixel of the second pixel being in contact, the second subpixel of the first pixel and the second subpixel of the second pixel being in contact, the third subpixel of the first pixel and the third subpixel of the third pixel being in contact, and
a set of photoelements comprising at least:
one first continuous array of photoelements which emits in a first wavelength range corresponding to the first color,
a second continuous array of photoelements which emit in a second wavelength range corresponding to the second color, the first wavelength range and the second wavelength range being distinct,
a third photoelement array which emits in a third wavelength range corresponding to the third color, the third wavelength range being distinct from the first wavelength range and the second wavelength range,
wherein the first subpixel of the first pixel and the first subpixel of the second pixel are both formed by the first array of photoelements, the second subpixel of the first pixel and the second subpixel of the second pixel box being formed by the second array of photoelements, the third subpixel of the first pixel and the third subpixel of the third pixel are both formed by the third array of photoelements,
and wherein a contact between the first pixel and the second pixel is made along a first contact line, and a contact between the first pixel and the third pixel is made along a second contact line, the first contact line and the second contact line forming an angle, referred to as a contact angle, of between 5° and 175°, preferably between 30° and 150°.

2. (canceled)

3. The display screen according to claim 1, wherein
third subpixel of the first pixel and the third subpixel of the second pixel are in contact and are both formed by the third array of photoelements.

4. (canceled)

5. (canceled)

6. (canceled)

7. The display screen according to the claim 1, wherein the contact angle is equal to 90°.

8. The display screen according to claim 1, wherein the contact angle is equal to 120°.

9. The display screen according to claim 1, wherein the third pixel further comprises a second subpixel of the second color in contact with the second subpixel of the first pixel, and wherein the second subpixel of the third pixel is formed by the second array of photoelements.

10. The display screen according to claim 9, wherein the plurality of pixels comprises at least one fourth pixel in contact with the second pixel and the third pixel, the fourth pixel comprising at least one second subpixel of the second color, the second subpixel of the second pixel and the second subpixel of the fourth pixel on the one hand, and the second subpixel of the third pixel and the second subpixel of the fourth pixel on the other hand, being in contact, and wherein the second subpixel of the fourth pixel is formed by the second array of photoelements.

11. The display screen according to claim 10, wherein the second pixel further comprises a third subpixel of the third color, and the fourth pixel further comprises a third subpixel of the third color, the third subpixel of the second pixel and the third subpixel of the fourth pixel being in contact, and both being formed by a third secondary continuous array of photoelements which emits in the third wavelength range.

12. The display screen according to claim 11, wherein the third pixel further comprises a first subpixel of the first color and the fourth pixel comprises at least one first subpixel of the first color, the first subpixel of the third pixel and the first subpixel of the fourth pixel being in contact, and both being formed by a first secondary continuous array of photoelements which emits in the first wavelength range.

13. The display screen according to claim 1, wherein the first array of photoelements extends over at least two pixels other than the first pixel and the second pixel.

14. The display screen according to claim 1, wherein each array of photoelements is common to at least two adjacent pixels, preferably to at least four adjacent pixels.

15. The display screen according to claim 1, wherein each array of photoelements forming a subpixel of the first pixel also forms at least one subpixel of at least one pixel adjacent to the first pixel.

16. The display screen according to claim 1, wherein the photoelements are configured to emit a beam whose intensity in a direction perpendicular to an upper face of a substrate from which said photoelements extend is at least 20% greater than the maximum intensity of an emission by a Lambertian light source whose total light flux over 4π sr is equal to the total flux over 4π sr of the beam emitted by the photoelements.

17. The display screen according to claim 1, wherein the first array of photoelements forms a photonic crystal.

18. The display screen according to claim 1, further comprising a plurality of electrical contacts configured to power the set of photoelements, the photoelements of arrays of photoelements forming distinct subpixels being powered by distinct electrical contacts.

19. The display screen according to claim 1, wherein the photoelements are nanowires.

20. The display screen according to claim 1, comprising a monolithic support carrying all the photoelements of the set of photoelements.
